(19) United States
(12) Patent Application Publication
(10) Pub. No.: US 2006/0003485 A1
(43) Pub. Date: Jan. 5, 2006

(54) Devices and methods of making the same

(76) Inventors: Randy L. Hoffman, Corvallis, OR (US); Peter P. Mardilovich, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/881,344

(22) Filed: Jun. 30, 2004

(51) Int. Cl. H01L 21/00

(52) U.S. Cl. 438/73; 438/149

(57) ABSTRACT

Devices including a substantially transparent dielectric and methods of forming such devices are disclosed.

### BACKGROUND

Electronic devices, such as integrated circuits, may include thin film transistors (TFT). A TFT generally includes a gate electrode, a gate dielectric, a drain electrode, a source electrode, and a thin film semiconductor (channel) layer.

Gate dielectrics may generally be formed by deposition or growth processes that involve high-temperature processing (either during deposition/growth or as a post-processing step) to achieve acceptable performance. Some types of dielectric materials that can be processed at relatively low temperatures may have reduced long-term stability or reliability. Further, some dielectric materials may impose an upper temperature limit on downstream thermal processing.

### BRIEF DESCRIPTION OF THE DRAWINGS

Objects, features and advantages will become apparent by reference to the following detailed description and drawings, in which like reference numerals correspond to similar, though not necessarily identical components. For the sake of brevity, reference numerals having a previously described function may not necessarily be described in connection with subsequent drawings in which they appear.

FIG. 1 is a process flow diagram of embodiments of a method of forming an embodiment of a device;

FIG. 2 is an enlarged cross-sectional view of an embodiment of the device;

FIG. 3 is an enlarged cross-sectional view of an embodiment of the device having a tantalum layer; device; and

FIG. 5 is an enlarged cross-sectional view of an alternate embodiment of the device.

### DETAILED DESCRIPTION

Embodiments of the disclosed method disclose processes for forming substantially transparent devices that may be used in circuits, including, but not limited to substantially transparent transistors and substantially transparent capacitors. The methods disclosed herein may be used in manufacturing processes, including, for example, integrating electrical circuits using mechanically flexible (e.g. plastic) substrates. One embodiment of the method includes forming a dielectric/gate dielectric via substantially complete anodization of a metal. This process may result in substantially transparent dielectrics/gate dielectrics with desired electrical properties. As referred to herein, substantially transparent, with reference to a structure, refers to transparency sufficient so that not less than about 50% of visible light energy incident on the structure is transmitted through the structure.

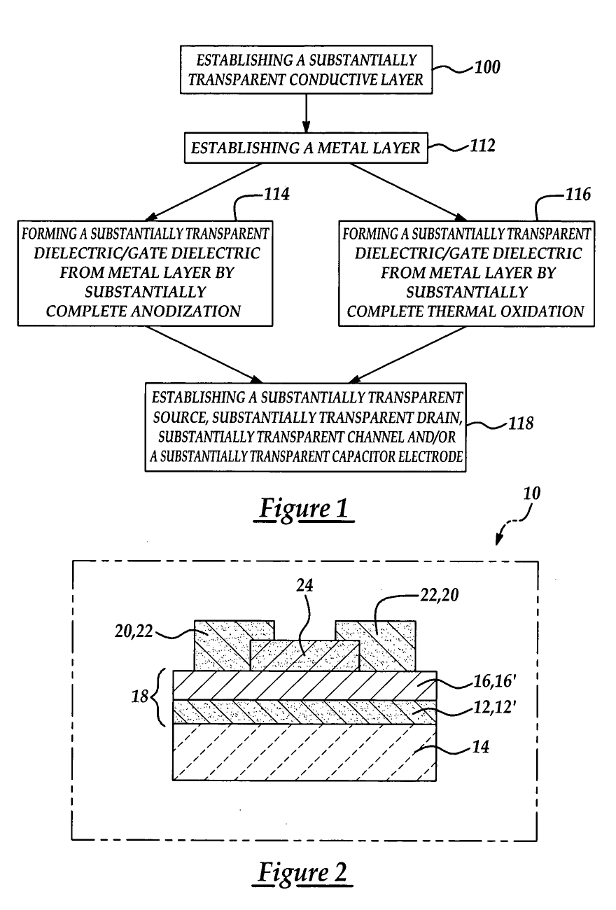

Referring now to FIG. 1, an embodiment of the method of making an embodiment of the substantially transparent device (non-limitative examples of which include substantially transparent transistors and capacitors) generally includes establishing a substantially transparent conductive layer 100, establishing at least one metal layer 112, forming a substantially transparent dielectric/gate dielectric from the metal layer by either substantially complete anodization 114 or substantially complete thermal oxidation 116, and establishing a substantially transparent source, a substantially transparent drain, a substantially transparent channel, and/or a substantially transparent capacitor electrode 118.

The various embodiments of the method form various embodiments of the substantially transparent devices. FIGS. 2 through 4 are non-limitative representations of some of these embodiments. It is to be understood that different embodiments of the method may result in substantially transparent devices having substantially similar or different configurations.

Referring now to FIG. 2, in an embodiment of the method for making a substantially transparent device 10 (e.g. a substantially transparent (thin film) transistor or a substantially transparent capacitor), a substantially transparent conductive layer 12 is established on a substantially transparent substrate 14. The substantially transparent conductive layer 12 may form a substantially transparent gate electrode 12′ (for a transistor) or a substantially transparent electrode 12′ (for a capacitor), depending on which device 10 is being fabricated. It is to be understood that any suitable material may be used for the substantially transparent conductive layer 12. In an embodiment, this material is a doped transparent semiconductor material. One non-limitative example of a suitable transparent semiconductor material is indium tin oxide (ITO). Other examples of suitable doped semiconductor materials include, but are not limited to n-type doped indium oxide, n-type doped zinc oxide, n-type doped tin oxide, and/or mixtures thereof.

Further, it is to be understood that any suitable material may be used for the substantially transparent substrate 14. Examples of suitable substantially transparent substrate 14 materials include, but are not limited to quartz, sapphire, glass, polycarbonates (PC), polyarylates (a non-limitative example of which is commercially available under the tradename ARYLITE from Promerus located in Brecksville, Ohio), polyethylene terephthalate (PET), polyestersulfones, polyimides (a non-limitative example of which is commercially available under the tradename KAPTON from DuPont located in Circleville, Ohio), polyolefins, polyethylene naphthalate (PEN), polyethersulfone (PES), polynorbornene (a non-limitative example of which is commercially available under the tradename APPEAR 3000 from Promerus located in Brecksville, Ohio), polyetheretherketone (PEEK), polyetherimide (PEI), and/or mixtures thereof.

The method further includes establishing one or more metal layer(s) 16 on the substantially transparent electrode/gate electrode 12′. It is to be understood that the metal selected for the one or more metal layer(s) 16 is dependent upon, among other factors, which embodiment of the method is being used to form the substantially transparent device 10.

The method further includes forming a substantially transparent dielectric/gate dielectric 16′. This may be accomplished by either substantially complete anodization of the metal layer(s) 16 or substantially complete thermal oxidation of the metal layer(s) 16. As referred to herein, substantially complete anodization or substantially complete oxidation refers to anodization or oxidation, respectively, performed to an extent such that the optical characteristics (for visible light) of device 10 are not significantly changed by further anodization or oxidation.

In an embodiment of the method, the established metal layer(s) 16 is substantially completely anodized throughout to form the substantially transparent dielectric/gate dielectric 16′. In this embodiment, the metal layer(s) 16 includes aluminum, tantalum, alloys thereof, and/or mixtures thereof. In an alternate embodiment, the metal layer(s) 16 includes one or more aluminum layer(s) and one or more tantalum layer(s). Other suitable metals for the anodization method may include, but are not limited to, bismuth, antimony, niobium, silver, cadmium, iron, magnesium, tin, tungsten, zinc, zirconium, titanium, copper, chromium, alloys thereof, and/or mixtures thereof. The thickness of the metal layer(s) 16 ranges between about 10 nm and about 500 nm. It is to be understood that the substantially complete anodization process forms an oxide of the selected metal. Thus, in a non-limitative embodiment(s), the formed substantially transparent dielectric/gate dielectric 16′ is aluminum oxide (alumina) and/or tantalum pentoxide.

In an embodiment, the substantially complete anodization of aluminum and/or tantalum may take place at room temperature, and/or, more generally, at any temperature above the freezing temperature and below the boiling temperature of the selected electrolyte. In a non-limitative example, aluminum is substantially completely anodized through using a citric acid electrolyte (C₆H₈O₇ or HOCOH₂C(OH)(COOH)CH₂COOH, 1 wt. % in water), an aluminum cathode (99.99% purity), and about 5 mA/cm² current density to achieve the desired and/or suitable voltage (anodization coefficient for anodic alumina in citric acid is ˜1.3 nm of alumina per 1 volt). Other non-limitative examples of suitable electrolytes include those based on boric acid (H₃BO₃), ammonium pentaborate ((NH₄)₂B₁₀O₁₆), ammonium tartrate (H₄NO₂CCH(OH)CH(OH)CO₂NH₄), and the like. In a non-limitative example, tantalum is substantially completely anodized using a platinum or stainless steel cathode and a boric acid electrolyte with pH adjusted to about 7 by ammonia, and a current density of about 0.05 mA/cm² to achieve the desired and/or suitable voltage and, as a result, thickness (anodization coefficient for anodic tantalum pentoxide is −1.8 nm of tantalum pentoxide per 1 volt).

It is to be understood that a dual anodization process may also optionally be used, for example, when oxidizing more than ˜350 nm of metal. This generally includes the fabrication of porous anodic alumina (oxalic acid, sulfuric acid, phosphoric acid, and/or mixtures thereof as electrolytes) and the fabrication of a barrier type of anodic alumina (non-limitative examples of which include citric acid, boric acid, ammonium pentaborate, and ammonium tartrate as electrolytes). Suitable solvents for this process include, but are not limited to water, alcohols, and/or mixtures thereof. It is to be understood that organic solvents may also be added to the solvent used. It is to be understood that for barrier type anodic alumina and tantalum pentoxide, anodized film thickness is a function of the anodization voltage (˜1.3 nm per volt for alumina and ˜1.8 nm per volt for tantalum pentoxide), while for porous oxides, the thickness is proportional to the cumulative charge density (i.e., film thickness is proportional to the product of anodization current density and the time for which this current flows, or the integrated anodization current density with respect to time).

In an alternate embodiment of the method, the metal layer(s) 16 is substantially completely thermally oxidized in air to form the substantially transparent dielectric/gate dielectric 16′. It is to be understood that nitrogen may also be a suitable atmosphere for nitridation [M+N₂—>MₓN_{y} or nitride], depending on the metal being oxidized. In this embodiment, the metal layer(s) 16 is tantalum and has a thickness ranging between about 10 nm and about 500 nm. The temperature of the substantially complete thermal oxidation ranges between about 300° C. and about 600° C. It is to be understood that a predetermined amount of tantalum is established for the metal layer(s) 16 and corresponds to a predetermined temperature such that a desired and/or suitable amount of tantalum pentoxide (the substantially transparent dielectric/gate dielectric 16′) is formed.

The combination of the substantially transparent dielectric/gate dielectric 16′ and the substantially transparent electrode/gate electrode 12′ forms a substantially transparent stack/gate stack 18 disposed on the substantially transparent substrate 14. It is to be understood that the substantially transparent stack/gate stack 18 may be subject to further processing steps (including the establishment of additional layers on the stack/gate stack 18 and/or between the layers of the stack/gate stack 18) and may ultimately be operatively disposed in the substantially transparent device 10.

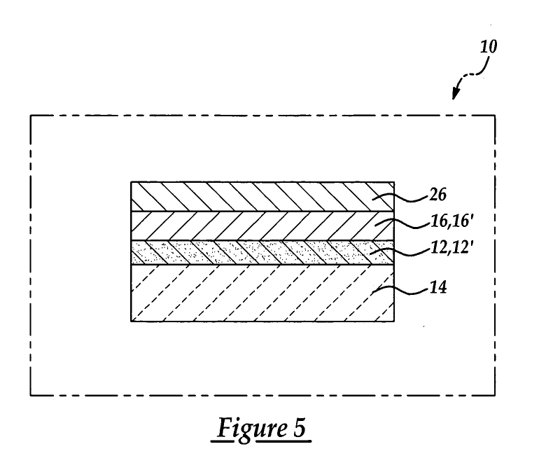

Whether the metal layer(s) 16 is substantially completely anodized or substantially completely thermally oxidized, the method may further include establishing a substantially transparent source 20, a substantially transparent drain 22, a substantially transparent channel 24, and/or a substantially transparent capacitor electrode 26 (as shown in FIG. 5) on the substantially transparent dielectric/gate dielectric 16′. It is to be understood that these substantially transparent elements 20, 22, 24 and 26 may be composed of any suitable materials, including, but not limited to substantially transparent semiconductor materials. Suitable non-limitative examples of these materials for a channel layer 24 include zinc oxide, tin oxide, cadmium oxide, indium oxide, n-type doped zinc oxide, n-type doped tin oxide, n-type doped cadmium oxide, n-type doped indium oxide, and/or mixtures thereof. Suitable non-limitative examples of these materials for source 20, drain 22, and capacitor electrode 26 include n-type doped zinc oxide, n-type doped tin oxide, n-type doped cadmium oxide, n-type doped indium oxide, and/or mixtures thereof.

As shown in the Figures, it is to be further understood that the source 20 and drain 22 may be interchangeable, i.e. if source 20 is on the left, drain 22 will be on the right; and if drain 22 is on the left, source 20 will be on the right.

It is to be understood that in an embodiment using substantially complete thermal oxidation, the substantially transparent source 20, drain 22, channel 24, and/or capacitor electrode 26 may be established either before or after the thermal oxidation of the metal (tantalum) layer(s) 16 in order to form the embodiment of the substantially transparent device 10 shown in FIG. 2.

Any suitable establishment (deposition) method may be used to deposit the substantially transparent conductive material/layer 12, the metal layer(s) 16, and the substantially transparent source 20, substantially transparent drain 22, substantially transparent channel 24, and the substantially transparent capacitor electrode, if employed. In an embodiment, establishing is accomplished by at least one of sputtering, chemical vapor deposition (CVD), atomic layer deposition (ALD), evaporation (e.g. thermal or e-beam), inkjet deposition, and/or spin-coating.

As described hereinabove, the substantially transparent device 10 illustrated in FIG. 2 may be formed by an embodiment of the method incorporating substantially complete anodization of the established metal layer(s) 16 or an embodiment of the method incorporating substantially complete thermal oxidation of the metal (tantalum) layer(s) 16 (either before or after the establishment of the substantially transparent source 20, drain 22, channel 24, and/or capacitor electrode 26).

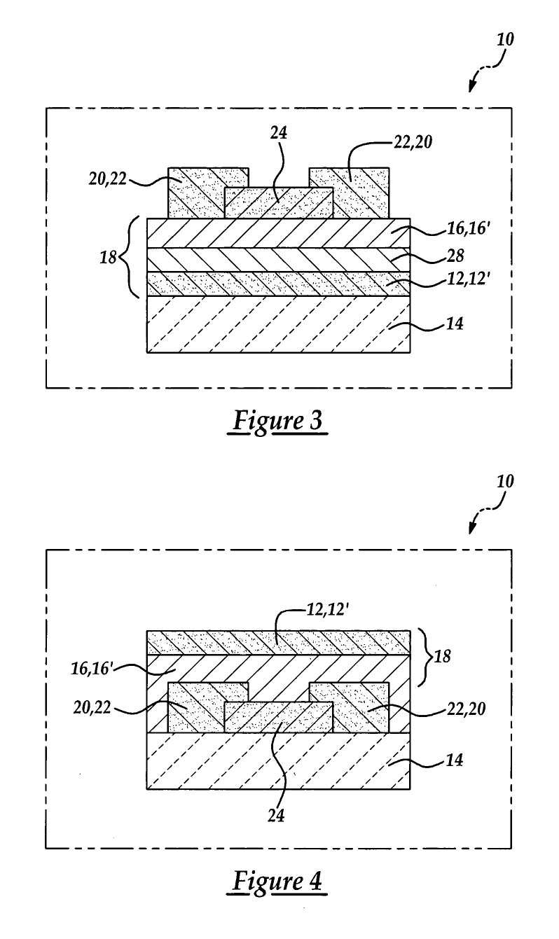

Referring now to FIG. 3, an embodiment of the method may optionally include establishing a layer 28 on the substantially transparent electrode/gate electrode 12′, prior to the establishment of the metal layer(s) 16. It is to be understood that this layer 28 may be disposed between the substantially transparent electrode/gate electrode 12′ and the substantially transparent dielectric/gate dielectric 16′ in the resulting substantially transparent device 10. The layer 28 includes tantalum, tantalum oxides, and/or mixtures thereof. In an embodiment, the thickness of the layer 28 ranges between about 1 nm and about 50 nm. One non-limitative embodiment includes a layer 28 having a thickness ranging between about 1 nm and about 10 nm. A non-limitative example of the layer 28 is tantalum.

Without being bound to any theory, it is believed that the addition of the layer 28 may advantageously aid in the substantially complete anodization of the metal layer(s) 16. The layer 28 may act as a conductor, thereby aiding in substantially fully and uniformly anodizing the metal layer(s) 16. It is further believed that the layer 28 may, in some instances, substantially prevent the break-down of the anodic alumina film, achieve an increase in the adhesion of the metal layer(s) 16, and/or may provide a substantially uniform electrical field distribution at the final stages of anodization.

FIG. 4 illustrates an alternate embodiment of the substantially transparent device 10. It is to be understood that the materials and establishment (deposition) techniques as previously described may be employed in this embodiment of the method.

The method includes first establishing the substantially transparent source 20, drain 22, the channel 24, and/or the capacitor electrode 26 on the substantially transparent substrate 14.

The metal layer(s) 16 is then established on the substantially transparent source 20, drain 22, the channel 24, and/or the capacitor electrode 26 and on any exposed portion of the substantially transparent substrate 14. In this embodiment, the metal layer(s) 16 is tantalum.

The substantially transparent conductive layer 12 is established on the metal layer(s) 16, thereby forming the substantially transparent electrode/gate electrode 12′. As depicted in FIG. 4, this embodiment of the substantially transparent device 10 has the substantially transparent electrode/gate electrode 12′ formed over the substantially transparent dielectric/gate dielectric 16′ as opposed to an embodiment where the substantially transparent dielectric/gate dielectric 16′ is formed over the substantially transparent electrode/gate electrode 12′ (see FIGS. 2 and 3).

The method further includes substantially completely thermally oxidizing the metal layer(s) 16 to form the substantially transparent dielectric/gate dielectric 16′. It is to be understood that the thermal oxidation process forms an oxide of the tantalum metal. Thus, in this embodiment, the formed substantially transparent dielectric/gate dielectric 16′ is tantalum pentoxide.

Embodiments of the device 10 include a substantially transparent substrate 14, a substantially transparent electrode 12′ or a substantially transparent gate electrode 12′, a substantially transparent dielectric or a substantially transparent gate dielectric 16′ (formed by either substantially complete anodization or thermal oxidation), and a substantially transparent source 20, drain 22, channel 24 and/or capacitor electrode 26. It is to be understood that the device 10 may be any suitable device, including, but not limited to substantially transparent thin film transistors and substantially transparent capacitors.

FIG. 5 shows a capacitor as the device 10, with a substantially transparent capacitor electrode 26 operatively disposed on the substantially transparent dielectric 16′.

A method of using an embodiment of the substantially transparent gate stack 18 disposed on a substantially transparent substrate 14 includes establishing the substantially transparent source 20 and the substantially transparent drain 22 on the substantially transparent gate stack 18. The method further includes operatively disposing the substantially transparent gate stack 18 having the source 20 and drain 22 disposed thereon in a device 10.

Embodiments of the devices 10 and methods of forming the same according to embodiments disclosed herein may be used for forming substantially transparent devices 10, including, but not limited to transistors and capacitors. The methods disclosed herein may be used in manufacturing processes, including, for example, integrating electrical circuits using mechanically flexible (e.g. plastic) substrates. Forming a substantially transparent dielectric/gate dielectric 16′ via substantially complete anodization of a metal layer 16 may result in substantially transparent dielectric/gate dielectrics 16′ having desirable electrical properties.

While embodiments have been described in detail, it will be apparent to those skilled in the art that the disclosed embodiments may be modified. Therefore, the foregoing description is to be considered exemplary rather than limiting.

What is claimed is:

1. A method for making a substantially transparent transistor, comprising:
establishing a substantially transparent conductive layer on a substantially transparent substrate, thereby forming a gate electrode;
establishing at least one metal layer on the gate electrode;
substantially completely anodizing the at least one metal layer, thereby forming a substantially transparent gate dielectric; and
establishing a substantially transparent source, a substantially transparent drain, and a substantially transparent channel on the substantially transparent gate dielectric.

2. The method as defined in claim 1 wherein the substantially transparent conductive layer comprises a doped substantially transparent semiconductor material.

3. The method as defined in claim 2 wherein the doped substantially transparent semiconductor material comprises at least one of n-type doped indium oxide, zinc oxide, tin oxide, indium tin oxide, and mixtures thereof.

4. The method as defined in claim 1 wherein the establishing is accomplished by at least one of sputtering, chemical vapor deposition, atomic layer deposition, thermal evaporation, electron beam evaporation, inkjet deposition, and spin-coating.

5. The method as defined in claim 1 wherein the at least one metal layer comprises at least one of aluminum, tantalum, alloys thereof, and mixtures thereof.

6. The method as defined in claim 1 wherein the at least one metal layer comprises at least one aluminum layer and at least one tantalum layer.

7. The method as defined in claim 1, further comprising establishing a layer of tantalum on the substantially transparent conductive layer prior to establishing the at least one metal layer.

8. The method as defined in claim 1 wherein the substantially transparent gate dielectric is at least one of aluminum oxide and tantalum pentoxide.

9. The method as defined in claim 1, wherein at least one of the substantially transparent source, the substantially transparent drain and the substantially transparent channel comprise at least one of indium oxide, tin oxide, zinc oxide, cadmium oxide, and mixtures thereof.

10. The method as defined in claim 1 wherein the substantially transparent substrate comprises at least one of quartz, sapphire, glass, polycarbonates, polyarylates, polyethylene terephthalate, polyestersulfones, polyimides, polyolefins, polyethylene naphthalate, polyethersulfone, polynorbornene, polyetheretherketone, polyetherimide, and mixtures thereof.

11. A substantially transparent transistor made by the method as defined in claim 1.

12. A method for making a device, comprising:
establishing a substantially transparent conductive layer on a substantially transparent substrate, to form a substantially transparent electrode;
establishing a tantalum layer on the substantially transparent electrode; and
thermally oxidizing in air the tantalum layer, thereby forming a substantially transparent dielectric.

13. The method as defined in claim 12 wherein the device is a transistor, the substantially transparent electrode is a substantially transparent gate electrode, and the substantially transparent dielectric is a substantially transparent gate dielectric.

14. The method as defined in claim 13 wherein the substantially transparent gate electrode and the substantially transparent gate dielectric form a substantially transparent gate stack, and wherein the method further comprises operatively disposing the substantially transparent gate stack in the transistor.

15. The method as defined in claim 13, further comprising establishing at least one of a substantially transparent source, a substantially transparent drain, and a substantially transparent channel on the tantalum layer prior to thermally oxidizing the tantalum layer.

16. The method as defined in claim 12 wherein the device is a capacitor.

17. The method as defined in claim 16, further comprising establishing a substantially transparent capacitor electrode on the tantalum layer.

18. The method as defined in claim 17 wherein the establishing of the capacitor electrode is accomplished prior to thermally oxidizing the tantalum layer.

19. The method as defined in claim 12 wherein thermally oxidizing the tantalum layer takes place at a temperature ranging between about 300° C. and about 600° C.

20. The method as defined in claim 12 wherein the substantially transparent conductive layer comprises at least one of n-type doped indium oxide, zinc oxide, tin oxide, indium tin oxide, and mixtures thereof.

21. The method as defined in claim 12 wherein the substantially transparent substrate comprises at least one of quartz, sapphire, glass, polycarbonates, polyarylates, polyethylene terephthalate, polyestersulfones, polyimides, polyolefins, polyethylene naphthalate, polyethersulfone, polynorbornene, polyetheretherketone, polyetherimide, and mixtures thereof.

22. A device made by the method as defined in claim 12.

23. A method for making a device, comprising:
establishing at least one of a substantially transparent source, a substantially transparent drain, a substantially transparent channel and a substantially transparent capacitor electrode on a substantially transparent substrate;
establishing a tantalum layer in overlying relationship to the substrate and the at least one substantially transparent source, substantially transparent drain, substantially transparent channel and substantially transparent capacitor electrode;
establishing a substantially transparent conductive layer on the tantalum layer, thereby forming one of a substantially transparent electrode and a substantially transparent gate electrode;
thermally oxidizing in air the tantalum layer, thereby forming one of a substantially transparent dielectric and a substantially transparent gate dielectric, wherein the one of the substantially transparent dielectric and the substantially transparent gate dielectric; and the one of the substantially transparent electrode and the substantially transparent gate electrode form one of a substantially transparent stack and a substantially transparent gate stack; and
operatively disposing the one of the substantially transparent stack and the substantially transparent gate stack in the device.

24. A method of making a substantially transparent transistor, comprising:
establishing a substantially transparent conductive layer on a substantially transparent substrate, thereby forming a substantially transparent gate electrode;
establishing a tantalum layer on the substantially transparent gate electrode;
thermally oxidizing the tantalum layer, thereby forming a substantially transparent gate dielectric; and
establishing a substantially transparent source, a substantially transparent drain and a substantially transparent channel on the substantially transparent gate dielectric, thereby forming the substantially transparent transistor.

25. The method as defined in claim 24 wherein thermally oxidizing the tantalum layer takes place at a temperature ranging between about 300° C. and about 600° C.

26. The method as defined in claim 24 wherein the substantially transparent conductive layer comprises at least one of n-type doped indium oxide, zinc oxide, tin oxide, indium tin oxide, and mixtures thereof.

27. The method as defined in claim 24 wherein the substantially transparent substrate comprises at least one of quartz, sapphire, glass, polycarbonates, polyarylates, polyethylene terephthalate, polyestersulfones, polyimides, polyolefins, polyethylene naphthalate, polyethersulfone, polynorbornene, polyetheretherketone, polyetherimide, and mixtures thereof.

28. A device, comprising:
a substantially transparent substrate;
one of a substantially transparent stack and a substantially transparent gate stack disposed on the substantially transparent substrate; and
one of a substantially transparent capacitor electrode; and a substantially transparent source and a substantially transparent drain disposed on the one of the substantially transparent stack and the substantially transparent gate stack;
wherein the one of the substantially transparent stack and the substantially transparent gate stack includes:
one of a substantially transparent electrode and a substantially transparent gate electrode disposed on the substantially transparent substrate, the one of the substantially transparent electrode and the substantially transparent gate electrode formed from a substantially transparent conductive material; and
one of a substantially transparent dielectric and a substantially transparent gate dielectric disposed on the one of the substantially transparent electrode and the substantially transparent gate electrode, the one of the substantially transparent dielectric and the substantially transparent gate dielectric formed from at least one substantially completely anodized metal layer.

29. The device as defined in claim 28 wherein the substantially transparent conductive material comprises at least one of n-type doped indium oxide, n-type doped zinc oxide, n-type doped tin oxide, n-type doped indium tin oxide, and mixtures thereof.

30. The device as defined in claim 28 wherein the substantially transparent substrate comprises at least one of quartz, sapphire, glass, polycarbonates, polyarylates, polyethylene terephthalate, polyestersulfones, polyimides, polyolefins, polyethylene naphthalate, polyethersulfone, polynorbornene, polyetheretherketone, polyetherimide, and mixtures thereof.

31. The device as defined in claim 28 wherein the metal layer comprises at least one of aluminum, tantalum, bismuth, antimony, niobium, silver, cadmium, iron, magnesium, tin, tungsten, zinc, zirconium, titanium, copper, chromium, alloys thereof, and mixtures thereof.

32. The device as defined in claim 28 wherein the device is a capacitor.

33. The device as defined in claim 28, further comprising a substantially transparent channel disposed on the substantially transparent gate stack.

34. An electronic device, comprising:
a substantially transparent substrate;
a substantially transparent gate stack disposed on the substantially transparent substrate; and
a substantially transparent source and a substantially transparent drain disposed on the substantially transparent gate stack;
wherein the substantially transparent gate stack is formed by a method, comprising:
establishing a substantially transparent conductive layer on the substantially transparent substrate, thereby forming a substantially transparent gate electrode;
establishing a tantalum layer on the substantially transparent conductive layer; and
thermally oxidizing the tantalum layer, thereby forming a substantially transparent gate dielectric.

35. The electronic device as defined in claim 34 wherein the substantially transparent conductive layer comprises at least one of n-type doped indium oxide, zinc oxide, tin oxide, indium tin oxide, and mixtures thereof.

36. The electronic device as defined in claim 34 wherein the substantially transparent substrate comprises at least one of quartz, sapphire, glass, polycarbonates, polyarylates, polyethylene terephthalate, polyestersulfones, polyimides, polyolefins, polyethylene naphthalate, polyethersulfone, polynorbornene, polyetheretherketone, polyetherimide, and mixtures thereof.

37. The electronic device as defined in claim 34 wherein the source and the drain are established on the tantalum layer of the substantially transparent gate stack prior to thermally oxidizing the tantalum layer.

38. The electronic device as defined in claim 34 wherein the source and the drain are established on the tantalum layer subsequent to thermally oxidizing the tantalum layer.

39. The electronic device as defined in claim 34 wherein thermally oxidizing the tantalum layer takes place at a temperature ranging between about 300° C. and about 600° C.

40. An electronic device, comprising:
a substantially transparent substrate;
a substantially transparent source and a substantially transparent drain disposed on the substantially transparent substrate; and
a substantially transparent gate stack disposed in overlying relationship to the substantially transparent substrate and the source and drain;
wherein the substantially transparent gate stack is formed by a method, comprising:
establishing a tantalum layer in overlying relationship to the substrate and the source and drain;
establishing a substantially transparent conductive layer on the tantalum layer, thereby forming a substantially transparent gate electrode; and
thermally oxidizing in air the tantalum layer, thereby forming a substantially transparent gate dielectric, wherein the substantially transparent gate dielectric and the substantially transparent gate electrode form the substantially transparent gate stack.

41. A thin film substantially transparent transistor, comprising:
a substantially transparent substrate;
a substantially transparent gate electrode disposed on the substantially transparent substrate, the substantially transparent gate electrode formed from a substantially transparent conductive material;
a substantially transparent gate dielectric disposed on the substantially transparent gate electrode, the substantially transparent gate dielectric formed from at least one completely anodized metal layer; and
a substantially transparent source and a substantially transparent drain disposed on the substantially transparent gate dielectric.

42. The transistor as defined in claim 41 wherein the substantially transparent conductive material comprises at least one of indium oxide, zinc oxide, tin oxide, indium tin oxide, and mixtures thereof.

43. The transistor as defined in claim 41 wherein the at least one completely anodized metal layer comprises one of aluminum oxide and tantalum pentoxide.

44. The transistor as defined in claim 41, further comprising a thin tantalum layer between the substantially transparent gate electrode and the substantially transparent gate dielectric, the thin tantalum layer having a thickness ranging between about 1 nm and about 50 nm.

45. The transistor as defined in claim 41, further comprising a substantially transparent channel disposed on the substantially transparent gate dielectric.

46. The transistor as defined in claim 41 wherein the substantially transparent substrate comprises at least one of quartz, sapphire, glass, polycarbonates, polyarylates, polyethylene terephthalate, polyestersulfones, polyimides, polyolefins, polyethylene naphthalate, polyethersulfone, polynorbornene, polyetheretherketone, polyetherimide, and mixtures thereof.

47. A method for making a substantially transparent electronic device, comprising:
establishing a substantially transparent conductive layer on a substantially transparent substrate, thereby forming one of a substantially transparent electrode and a substantially transparent gate electrode;
establishing at least one metal layer on the one of the substantially transparent electrode and the substantially transparent gate electrode;
forming one of a substantially transparent dielectric and a substantially transparent gate dielectric from the at least one metal layer by one of substantially complete anodization and thermal oxidation; and
establishing at least one of a substantially transparent capacitor electrode, a substantially transparent source, a substantially transparent drain and a substantially transparent channel on the one of the substantially transparent dielectric and the substantially transparent gate dielectric, thereby forming the substantially transparent electronic device.

48. The method as defined in claim 47 wherein the electronic device is one of a transistor and a capacitor.

49. The method as defined in claim 47, further comprising establishing a tantalum layer on the substantially transparent conductive layer prior to forming the one of the substantially transparent dielectric and the substantially transparent gate dielectric.

50. A method for making a substantially transparent electronic device, comprising:
establishing a substantially transparent conductive layer on a substantially transparent substrate, thereby forming one of a substantially transparent electrode and a substantially transparent gate electrode;
step for forming one of a substantially transparent dielectric and a substantially transparent gate dielectric on the one of the substantially transparent electrode and the substantially transparent gate electrode; and
establishing at least one of a substantially transparent capacitor electrode, a substantially transparent source, a substantially transparent drain and a substantially transparent channel on the one of the substantially transparent dielectric and the substantially transparent gate dielectric, thereby forming the substantially transparent electronic device.

51. A method of using a substantially transparent gate stack, comprising:
establishing a substantially transparent source and a substantially transparent drain on the substantially transparent gate stack, the substantially transparent gate stack including a substantially transparent substrate, a substantially transparent gate electrode disposed on the substantially transparent substrate, and a substantially transparent gate dielectric disposed on the substantially transparent gate electrode, the substantially transparent gate dielectric formed from one of substantially complete anodization of a metal layer and thermal oxidation of a metal layer; and
operatively disposing the substantially transparent gate stack having the source and drain disposed thereon in an electronic device.

52. A method for making a device, comprising:
establishing a substantially transparent conductive layer on a substantially transparent substrate, to form a substantially transparent electrode;
establishing a metal layer on the substantially transparent electrode; and
substantially completely anodizing the metal layer, thereby forming a substantially transparent dielectric.

53. The method as defined in claim 52 wherein the metal layer comprises at least one of aluminum, tantalum, alloys thereof, and mixtures thereof.

54. The method as defined in claim 52 wherein the device is a transistor, the substantially transparent electrode is a substantially transparent gate electrode, and the substantially transparent dielectric is a substantially transparent gate dielectric.

55. The method as defined in claim 54 wherein the substantially transparent gate electrode and the substantially transparent gate dielectric form a substantially transparent gate stack, and wherein the method further comprises operatively disposing the substantially transparent gate stack in the transistor.

56. The method as defined in claim 54 wherein the substantially transparent gate dielectric is at least one of aluminum oxide and tantalum pentoxide.

57. A device, comprising:
a substantially transparent substrate;
a substantially transparent electrode on the substantially transparent substrate; and
a substantially transparent dielectric formed of a substantially completely anodized metal layer on the substantially transparent electrode.

58. The device as defined in claim 57 wherein the substantially completely anodized metal layer comprises at least one of aluminum oxide and tantalum pentoxide.

59. The device as defined in claim 57 wherein the substantially transparent dielectric is a substantially transparent gate dielectric and wherein the device further comprises at least one of a substantially transparent source, a substantially transparent drain, and a substantially transparent channel on the substantially transparent gate dielectric.

60. The device as defined in claim 57, further comprising a capacitor electrode on the substantially transparent dielectric.

61. A device, comprising:
a substantially transparent substrate;
a substantially transparent electrode on the substantially transparent substrate; and
a substantially transparent dielectric formed of thermally oxidized tantalum on the substantially transparent electrode.

62. The device as defined in claim 61, wherein the device is a transistor, the substantially transparent dielectric is a substantially transparent gate dielectric, and wherein the device further comprises a transparent source and drain on the substantially transparent gate dielectric.

63. The device as defined in claim 62 wherein the source and the drain are established on the substantially transparent gate dielectric prior to thermally oxidizing the tantalum.

64. The device as defined in claim 62 wherein the source and the drain are established on the substantially transparent gate dielectric subsequent to thermally oxidizing the tantalum.
